(19) United States
(12) Patent Application Publication
(10) Pub. No.: US 2016/0216352 A1
(43) Pub. Date: Jul. 28, 2016

(54) DIXON MAGNETIC RESONANCE IMAGING

(71) Applicant: KONINKLIJKE PHILIPS N.V., Eindhoven (NL)

(72) Inventors: HOLGER EGGERS, EINDHOVEN (NL); GABRIELE MARIANNE BECK, EINDHOVEN (NL); MARIUS JOHANNES VAN MEEL, EINDHOVEN (NL); MICHEL PAUL JURRIAAN JURRISSEN, EINDHOVEN (NL); ADRIANUS JOSEPH WILLIBRORDUS DUIJNDAM, EINDHOVEN (NL)

(21) Appl. No.: 14/914,899

(22) PCT Filed: Aug. 27, 2014
(86) PCT No.: PCT/EP2014/068112

§ 371 Date: Feb. 26, 2016

(30) Foreign Application Priority Data
Aug. 30, 2013 (EP) 13182426.0

(51) Int. Cl. G01R 33/48; G01R 33/56

(52) U.S. Cl. CPC G01R 33/4828; G01R 33/5608

(57) ABSTRACT

The invention provides for a magnetic resonance imaging system (300, 400) for acquiring magnetic resonance data (342) from an imaging zone (308). The magnetic resonance imaging system comprises a processor (330) for controlling the magnetic resonance imaging system. Execution of instructions cause the processor to acquire (100, 200) the magnetic resonance data using a Dixon pulse sequence (340) to control the magnetic resonance imaging system; reconstruct (102, 202) a water image (346, 504, 1424) and a fat image (344, 506, 1422) from the acquired magnetic resonance data, wherein the water image comprises a first set of complex valued voxels, wherein the fat image comprises a second set of complex valued voxels; calculate (104, 204) a modified image (348, 902, 1440, 1502, 1602, 1700, 1702, 1704, 1706, 1708) comprising a first set of real valued voxels, wherein the set of real valued voxels is calculated as follows: for each voxel, its real value is calculated by taking the n-th root of the weighted sum of the modulus of the complex value at the corresponding voxel of the first set of complex valued voxels raised to the power n and modulus of the complex value at the corresponding voxel of the second set of complex valued voxels raised to the power n, with n>1.

### TECHNICAL FIELD

The invention relates to Dixon methods of magnetic resonance imaging, in particular to the reduction of ghosting in magnetic resonance images.

### BACKGROUND OF THE INVENTION

A large static magnetic field is used by Magnetic Resonance Imaging (MRI) scanners to align the nuclear spins of atoms as part of the procedure for producing images within the body of a patient. This large static magnetic field is referred to as the B0 field.

During an MRI scan, Radio Frequency (RF) pulses generated by a transmitter coil cause perturbations to the local magnetic field, and RF signals emitted by the nuclear spins are detected by a receiver coil. These RF signals are used to construct the MRI images. These coils can also be referred to as antennas. Further, the transmitter and receiver coils can also be integrated into a single transceiver coil that performs both functions. It is understood that the use of the term transceiver coil also refers to systems where separate transmitter and receiver coils are used. The transmitted RF field is referred to as the B1 field.

MRI scanners are able to construct images of either slices or volumes. A slice is a thin volume that is only one voxel thick. A voxel is a small volume over which the MRI signal is averaged, and represents the resolution of the MRI image. A voxel may also be referred to as a pixel herein.

Dixon methods of magnetic resonance imaging include a family of techniques for producing separate water and lipid (fat) images. The various Dixon techniques such as, but not limited to, two-point Dixon Method, three-point Dixon method, four-point Dixon method, and six-point Dixon Method are collectively referred to herein as Dixon techniques or methods. The terminology to describe the Dixon technique is well known and has been the subject of many review articles and is present in standard texts on Magnetic Resonance Imaging. For example “Handbook of MRI Pulse Sequences” by Bernstein et. al., published by Elsevier Academic Press in 2004 contains a review of some Dixon techniques on pages 857 to 887.

The journal article Huang et. al., “Data Convolution and Combination Operation (COCOA) for Motion Ghost Artifacts Reduction,” Magnetic Resonance in Medicine 64: 157-166 (2010) describes a method of correcting k-space corrupted by motion for k-space data acquired using multiple element acquisition techniques.

The journal article Fuller et. al., “Iterative Decomposition of Water and Fat with Echo Asymmetry and Least-Squares Estimation (IDEAL) Fast Spin-Echo Imaging of the Ankle: Initial Clinical Experience,” discloses an iterative method of decomposing the water and fat signals in combination with fast spin-echo imaging.

The ISMRM-2004 (p. 2686) abstract mentions that recombination of water and fat images after correction for the displacement artifact may be valuable for anatomical references.

The US-patent application US2007/0285094 mentions that to recombine water and fat images in various recombinations may be helpful for particular diagnostic considerations. The recombined ‘in-phase’ images may be calculated as the sum of the modulus-values of the water and fat images.

### SUMMARY OF THE INVENTION

The invention provides for a magnetic resonance imaging system, a method of operating the magnetic resonance imaging system and a computer program product in the independent claims. Embodiments are given in the dependent claims.

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wireline, optical fiber cable, RF, etc., or any suitable combination of the foregoing. A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage is any non-volatile computer-readable storage medium. In some embodiments computer storage may also be computer memory or vice versa.

A ‘processor’ as used herein encompasses an electronic component which is able to execute a program or machine executable instruction or computer executable code. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. The computer executable code may be executed by multiple processors that may be within the same computing device or which may even be distributed across multiple computing devices.

Computer executable code may comprise machine executable instructions or a program which causes a processor to perform an aspect of the present invention. Computer executable code for carrying out operations for aspects of the present invention may be written in any combination of one or more programming languages, including an object oriented programming language such as Java, Smalltalk, C++ or the like and conventional procedural programming languages, such as the “C” programming language or similar programming languages and compiled into machine executable instructions. In some instances the computer executable code may be in the form of a high level language or in a pre-compiled form and be used in conjunction with an interpreter which generates the machine executable instructions on the fly.

The computer executable code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It will be understood that each block or a portion of the blocks of the flowchart, illustrations, and/or block diagrams, can be implemented by computer program instructions in form of computer executable code when applicable. It is further understood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, gear sticks, steering wheel, pedals, wired glove, dance pad, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘display’ or ‘display device’ as used herein encompasses an output device or a user interface adapted for displaying images or data. A display may output visual, audio, and or tactile data. Examples of a display include, but are not limited to: a computer monitor, a television screen, a touch screen, tactile electronic display, Braille screen, Cathode ray tube (CRT), Storage tube, Bistable display, Electronic paper, Vector display, Flat panel display, Vacuum fluorescent display (VF), Light-emitting diode (LED) displays, Electroluminescent display (ELD), Plasma display panels (PDP), Liquid crystal display (LCD), Organic light-emitting diode displays (OLED), a projector, and Head-mounted display.

Magnetic Resonance (MR) data is defined herein as being the recorded measurements of radio frequency signals emitted by atomic spins by the antenna of a Magnetic resonance apparatus during a magnetic resonance imaging scan. Magnetic resonance data is an example of medical image data. A Magnetic Resonance Imaging (MRI) image is defined herein as being the reconstructed two or three dimensional visualization of anatomic data contained within the magnetic resonance imaging data. This visualization can be performed using a computer.

In one aspect the invention provides for a magnetic resonance imaging system for acquiring magnetic resonance data from an imaging zone. The magnetic resonance imaging system comprises a processor for controlling the magnetic resonance imaging system. The magnetic resonance imaging system further comprises a memory. The memory contains machine-executable instructions for execution by a processor. The memory further contains a specification of a pulse sequence for performing a Dixon magnetic resonance imaging method. A pulse sequence as used herein encompasses a set of commands or instructions which can be converted into commands which control the operation of the magnetic resonance imaging system to acquire the magnetic resonance data. The particular imaging technique which is applied is determined by the pulse sequence.

A specification of a pulse sequence refers to the commands for performing the Dixon method or commands which may be converted into the specific instructions for controlling the magnetic resonance imaging system to perform the Dixon method. Dixon methods for suppressing the lipid signal in magnetic resonance imaging are well known and are of the topic of several review articles and chapters in texts on magnetic resonance imaging. For instance pages 857-877 of the Handbook of MRI Pulse Sequences by Bernstein et. al. reviews the Dixon technique. The terminology referring to the water image, fat image, in-phase and out-of-phase images use the terminology discussed in the Handbook of MRI Pulse Sequences.

Execution of the instructions causes the processor to acquire the magnetic resonance data using the Dixon Pulse Sequence to control the magnetic resonance imaging system. The use of the term Dixon Pulse Sequence as used herein encompasses the various Dixon techniques. For instance the Dixon Pulse Sequence may be applicable for performing a two-point, three-point, four-point, or other Dixon method. Next, execution of the instructions further causes the processor to reconstruct a water image and a fat image from the acquired magnetic resonance data. The water image comprises a first set of complex valued voxels. The fat image comprises a second set of complex valued voxels. Execution of the instructions further causes the processor to calculate a modified image comprising a first set of real valued voxels. The set of real valued voxels is calculated by taking the nth root of the weighted sum of the modulus of the first set of complex valued voxels raised to the power of n and the modulus of the second set of complex valued voxels raised to the power n. In other words, for each voxel, its real value is calculated by taking the n^{th} root of the weighted sum of the modulus of the complex value at the corresponding voxel of the first set of complex valued voxels raised to the power n and modulus of the complex value at the corresponding voxel of the second set of complex valued voxels raised to the power n, with n>1. The modulus of a complex value as used herein encompasses finding the positive value of the length of the vector representing the complex value. Complex values may for instance be represented in polar form. The modulus would be the length of the vector. If the complex value is represented in real and imaginary components then the modulus would be the complex value times its conjugate which is then taken the square root of.

This embodiment may have the benefit that noise or artifacts which are present in just the fat or the water image may be less visible. It may therefore be easier for a physician or other healthcare professional to interpret the modified image. A weighted sum as used herein encompasses multiplying either the modulus of the first set of complex valued voxels and/or the modulus of the second set of complex valued voxels by a constant before adding them. That is to say when we first find the module of the first set of complex valued voxels raised to the power n then one would calculate the modulus of the second set of complex valued voxels raised to the power of n and then would multiply either or both of these by the same or different constants to weight them. n may also be referred to as “N” herein.

In some embodiments both of the terms would be weighted positively and you would have an image that would be similar to an in-phase image that is typical for the Dixon technique. In other cases one of the terms would be weighted positively and one negative and then the image would be similar to an out-of-phase image that is typical for the Dixon technique. When discussing how this modified image is calculated, it is understood that it is performed on each particular voxel individually. That is there is a voxel in the water image that corresponds to a voxel in the fat image that corresponds to a voxel in the modified image.

In another embodiment execution of the instructions further cause the processor to apply a water-fat shift correction to the fat image before calculating the modified image. This for instance may comprise applying a water-fat shift correction to the fat image dataset correcting the expected voxel shift in the readout direction defined by the frequency bandwidth and/or by registering the fat image dataset relative to the water image dataset.

In another embodiment execution of the instructions further cause the processor to apply a B0 correction to the magnetic resonance data before reconstructing the fat image and the water image. A B0 correction as used herein is a correction to the magnetic resonance data to take into account inhomogeneities of the main magnetic field which is also referred to as the B0 field.

In another embodiment execution of the instructions further cause the processor to multiply the modulus of the second set of complex valued voxels to the power n by a fat weighting constant before adding the modules to the second set of complex value voxels to the power n to the first set of complex value voxels to the power n wherein the fat weighting constant is preferably between 0.01 and 0.99. Alternatively, the fat weighting constant is preferably between 0.01 and 0.9. Alternatively the fat weighting constant is preferably between 0.05 and 0.15. n is an integer greater than or equal to 1. This embodiment may be advantageous in some situations because the use of a fat weighting constant less than 1 may reduce the visibility of ghosting in the modified image.

In another embodiment execution of the instructions further cause the processor to multiply the modulus of the first set of complex valued voxels to the power n by a water weighting constant before adding the modulus of the second set of complex valued voxels to the power n to the modulus of the first set of complex valued voxels to the power n. The water weighting constant is preferably between 0.01 and 0.99. Alternatively the water weighting constant may be between 0.01 and 0.9. The water weighting constant may alternatively be between 0.05 and 0.15. n is an integer greater than or equal to 1. This embodiment may have the advantage that the visibility of ghosting due to motion of the subject may be reduced in some cases.

In another embodiment execution of the instructions further cause the processor to calculate a reference image. The reference image is a Dixon in-phase image or a Dixon out-of-phase image constructed from the water image and the fat image using complex addition and/or subtraction with or without weighing water and fat voxels. Execution of the instructions further cause the processor to calculate a ghosting image by subtracting the reference image and the modified image from each other. In some examples, the weighing factor of water and fat voxels in both the reference and modified image may be identical.

The modified image may resemble an in-phase image or an out-of-phase image depending upon how the weighting is constructed between the first term and the second term. When calculating the ghosting image if the reference image is a Dixon in-phase image then the modified image should resemble an in-phase image. If the reference image resembles a Dixon out-of-phase image then the modified image should resemble an out-of-phase image. That is to say the first and second terms should have opposite values and be weighted such that one is positive and one is negative. Execution of the instructions further cause the processor to identify a set of ghosted voxels by thresholding the ghosting image. For instance voxels with a magnitude above a certain value may be referred to as ghosted voxels. For the identification of ghosted voxels, the modified image is calculated with the power parameter n of the invention in the range n>1.

Execution of the instructions further cause the processor to calculate a corrected image using a set of ghosted voxels to locate ghosting artifacts due to motion. This embodiment may be beneficial because comparing the reference image and the modified image enables the identification of ghosting artifacts due to motion of the subject during the acquisition of the magnetic resonance data. There are a number of different methods that can be used to correct the image. These include k-space methods and also image processing methods or also a combination of both k-space and image processing methods.

With the description and claims the labels for images are selected to enable the clearest interpretation. In some cases the images are given standard names or labels which aid the reader in distinguishing what the image is useful for. A water image as used herein encompasses an image. A fat image as used herein encompasses an image. However, the water image and fat image are obtained using a Dixon's method, and this standard terminology is understood by the skilled individual. A modified image as used herein encompasses an image. In contrast, “modified image” is simply a label. The term “modified” is used because it is an image which is not constructed in the normal way a Dixon in-phase or out-of-phase image would be constructed. It is more useful to use the term “modified image” than simply calling it for example a “first image.”

A reference image as used herein encompasses an image. A Dixon in-phase image as used herein encompasses an image. A Dixon out-of-phase image as used herein encompasses an image. A ghosting image as used herein encompasses an image. A corrected image as used herein encompasses an image.

In another embodiment execution of the instructions further cause the processor to identify a water-fat transition area in the corrected image using the fat image and the water image. Typically using the Dixon method, the signal from water and fat is separated into two separate images. By using something such as a lower threshold or an edge detection algorithm the boundary of a water-fat transition can be identified in the two images. Execution of the instructions further cause the processor to remove ghosted voxels within the water-fat transition area from the set of ghosted voxels. At the water-fat transition area there may be some voxels which are falsely identified as being ghosted voxels due to for instance motion of the subject. By eliminating ghosted voxels within a certain distance of a water-fat transition the correction of the image due to motion as indicated by the ghosted voxels may be improved.

In another embodiment execution of the instructions further cause the processor to calculate the corrected image at least partially by iteratively modifying k-space lines from the magnetic resonance data to minimize the number of voxels in the set of ghosted voxels after recalculating the water image, the fat image, the modified image, and the reference image. Modifying the k-space as used herein encompasses deleting or correcting elements from k-space and using iterative reconstruction methods or data convolution and combination operations to synthesize a motion corrected image. For instance the so called data convolution and combination operations (COCOA) may be applied [detailed in Magnetic Resonance in Medicine, Volume 64, pages 157-166 published in 2010]. This embodiment may also be useful with parallel imaging techniques where different antenna elements acquire overlapping regions of k-space and where iterative reconstruction methods can be used [detailed in Magnetic Resonance in Medicine 66:1339-1345 (2011), In this embodiment the whole process of going through and calculating a set of ghosted voxels is repeated iteratively. During each iteration k-space consistency methods such as COCOA may be used for identifying, selecting and modifying inconsistent k-space lines. Looking at the set of ghosted voxels by for instance counting them or rather determining the size of the set of ghosted voxels in the region can be used to determine if modifying the k-space lines reduced the ghosting. Note that the ghosted voxel image and the Dixon image is used to determine if the artifact level is improved and signal to noise is still above a specified signal to noise criteria.

In another embodiment execution of the instructions further cause the processor to calculate the corrected image at least partially by replacing each of the ghosted voxels in the corrected image by averaging voxels of predetermined distance around each of the ghosted voxels. In this embodiment a neighborhood or region around a ghosted voxel is determined and the ghosted voxel is determined by the average value in the region or neighborhood. This may be a particularly good way of replacing small groups of ghosted voxels or isolated voxels.

In another embodiment execution of the instructions further cause the processor to calculate the corrected image at least partially by replacing each of the set of ghosted voxels in the corrected image by identifying the regions of the ghosted voxels and averaging the voxels bordering the regions of the ghosted voxels. In this embodiment regions of ghosted voxels are identified and then the borders of the ghosted voxels are then used to create an average. For instance, for ghosting induced by motion of a subject there may be interfering lines. These lines of ghosted voxels could be identified as the sets of ghosted voxels and then the unghosted voxels which border those may be used to average to cover up these lines.

In another embodiment execution of the instructions further cause the processor to calculate the corrected image at least partially by multiplying each of the set of ghosted voxels in the corrected image by a predetermined correction factor. In this case the ghosted voxels are simply multiplied by a constant or a correction factor to change the value of the ghosted voxel. This may help to make the ghosted voxels less visible in the image.

In another embodiment the corrected image is any one of the following: a corrected water image, a corrected fat image, a corrected Dixon in-phase image, and/or a corrected Dixon out-of-phase image. These different types of images are supplied as following. A corrected water image as used herein encompasses a water image calculated using a Dixon method. A corrected fat image as used herein encompasses a fat image calculated using a Dixon method. A corrected Dixon in-phase image encompasses a Dixon in-phase image calculated using a Dixon method. A corrected Dixon out-of-phase image encompasses a Dixon out-of-phase image calculated using a Dixon method.

In another embodiment the modified image is calculated using a formula algebraically equivalent to Mᵢ=(w_{w}|Wᵢ|ⁿ+w_{f}|Fᵢ|ⁿ)^{1/n}.

In this formula Mᵢ is the ith voxel of the modified image. Wi is the ith voxel of the water image. Fᵢ is the ith voxel of the fat image. w_{w} is a water weighting constant. w_{f} is a fat weighting constant.

This formula may be interpreted as one implementation of the mathematical process described in the main independent claim of the magnetic resonance imaging system.

In another embodiment the ratio w_{f} divided by w_{w} is positive. In this embodiment the modified image is equivalent to an in-phase image constructed using a Dixon method.

In another embodiment the ratio w_{f} divided w_{w} is negative. In this embodiment the modified image is equivalent to an out-of-phase image constructed using a Dixon method.

In another embodiment a modified in-phase image is calculated by adding a weighted water image to a weighted fat image with a weighting constant of water and fat in between 0.01 and 1. They are preferably between 0.85 and 1. The value n is unequal to 1.

In another embodiment a modified out-of-phase image is calculated by adding a weighted water image to a weighted fat image with a weighting constants of water in between 0.01 and 1, preferably between 0.85 and 1 and the weighting factor of the fat image is in between −0.01 and −1. The weighting factor of the fat image is preferably between −0.85 and −1. The value of n is unequal to 1.

In another embodiment n is greater than 1.

In another embodiment n is less than 1.

In another embodiment n=1.

In another embodiment the invention provides for a method of operating the magnetic resonance imaging system. The magnetic resonance imaging system is operable for acquiring magnetic resonance data from an imaging zone. This comprises the step of acquiring the magnetic resonance data using a Dixon Pulse Sequence to control the magnetic resonance imaging system. The method further comprises the step of reconstructing a water image and a fat image from the acquired magnetic resonance data. The water image comprises a first set of complex valued voxels. The fat image comprises a second set of complex valued voxels. The method further comprises the step of calculating a modified image comprising a first set of real valued voxels. The set of real valued voxels is calculated by taking the nth root of the weighted sum of the modulus of the first set of complex valued voxels raised to the power n and the modulus of the second set of complex valued voxels raised to the power n.

In another aspect the invention provides for a computer program product comprising machine-executable instructions for execution by a processor controlling the magnetic resonance imaging system for acquiring magnetic resonance data from an imaging zone. Execution of the instructions causes the processor to acquire the magnetic resonance data using a Dixon Pulse Sequence to control the magnetic resonance imaging system. Execution of the instructions further causes the processor to reconstruct a water image and a fat image from the acquired magnetic resonance data. The water image comprises a first set of complex valued voxels. The fat image comprises the second set of complex valued voxels. Execution of the instructions further causes the processor to calculate a modified image comprising a first set of real valued voxels. The set of real valued voxels is calculated by taking the nth root of the weighted sum of the modulus of the first set of complex valued voxels raised to the power n and the modulus of the second set of complex valued voxels raised to the power n.

In another aspect the invention provides for a magnetic resonance imaging system for acquiring magnetic resonance data from an imaging zone. The magnetic resonance imaging system comprises a processor for controlling the magnetic resonance imaging system. The magnetic resonance imaging system further comprises a memory containing machine-executable instructions for execution by the processor and a specification of a pulse sequence for performing a Dixon magnetic resonance imaging method. Execution of the instructions causes the processor to acquire the magnetic resonance data using the Dixon Pulse Sequence to control the magnetic resonance imaging system. Execution of the instructions further causes the processor to reconstruct a water image and a fat image from the acquired magnetic resonance data. The water image comprises a first set of complex valued voxels. The fat image comprises a second set of complex valued voxels. Execution of the instructions further cause the processor to calculate a modified image comprising a third set of voxels. In some instances the modified image in this example may be substituted for the modified image in the previously mentioned embodiments.

The processor is programmed to calculate the value of a function and to calculate the inverse of the function. The third set of voxels is calculated by applying the inverse of the function to the sum of the function applied to the first set of complex valued voxels and the function applied to the second set of complex valued voxels. The function is invertible to calculate the inverse of the function. The function applied to the value 0 has the value of 0. The second derivative of the function is positive for the first set of complex valued voxels and the second set of complex valued voxels. In other words the second derivative of the function is positive for the domain over which the function is applied. This example is an alternative to the use of the modulus in the previously mentioned embodiments.

This example can alternatively be described as:

Mᵢ=g⁻¹(g(w)+g(f)), wherein g(x) is a function and g⁻¹(x) is its inverse,

and for which the next conditions hold:

1) g is invertible

2) g(0)=0

3) the 2nd derivative of g is positive, in particular strictly positive on the domain over which it is used.

A specific example of this is:

Mᵢ=((Wᵢ+Fᵢ)/a)*log(exp(a*Wᵢ/(Wᵢ+Fᵢ)+exp(a*Fᵢ(Wᵢ+Fᵢ)−1), where a is a constant and the other variables are as was previously defined. For a=2, the above formula behaves quite similar to modulus addition of the water and fat images.

In another example of the modulus of the first set of complex valued voxels is taken before the function is applied to it. Also in this example the modulus of the second set of complex valued voxels is taken before the function is applied to it also. So in other words the magnitude of the voxels is determined before the function is applied to it and they are added together.

In another example the sum of the two functions is a weighted sum where one or both of them has a value multiplied by them to represent a weighting between the two images.

It is understood that one or more of the aforementioned embodiments of the invention may be combined as long as the combined embodiments are not mutually exclusive.

### BRIEF DESCRIPTION OF THE DRAWINGS

In the following preferred embodiments of the invention will be described, by way of example only, and with reference to the drawings in which:

FIG. 1 shows a flow chart which illustrates a method;

FIG. 2 shows a flow chart which illustrate a further method;

FIG. 3 illustrates an example of a magnetic resonance imaging system;

FIG. 4 illustrates a further example of a magnetic resonance imaging system;

FIG. 5 shows a simple schematic diagram which illustrates the components of various images;

FIG. 6 shows a further simple schematic diagram which illustrates the components of various images;

FIG. 7 shows a magnetic resonance in-phase image of a foot that was acquired using a Dixon method and constructed using modulus addition;

FIG. 8 shows a further image reconstructed using the same water and fat image of FIG. 7 except the water image was weighted by a factor of 1 and the fat image was weighted by a factor of 0.1;

FIG. 9 illustrates the calculation of a ghosting image;

FIG. 10 shows a fat image;

FIG. 11 shows a water image;

FIG. 12 is an image which was reconstructed using modulus addition of FIGS. 10 and 11;

FIG. 13 shows an image reconstructed using complex addition of FIGS. 10 and 11;

FIG. 14 shows several diagrams which illustrate the benefit of using in-phase addition of the water and fat images;

FIG. 15 illustrates the calculation of a ghosting image;

FIG. 16 shows a transverse cross-sectional view of the lower mandible and skull; Image 1600 has all the images in FIGS. 16-21 were acquired using a Dixon technique.

FIG. 17 shows the resulting image for the modulus addition of different powers of n using the same data a FIG. 16;

FIG. 18 compares two different module addition images using the data of FIG. 16;

FIG. 19 further compares two different module addition images using the data of FIG. 16;

FIG. 20 compares two different module addition images using the data of FIG. 16; and

FIG. 21 compares two different module addition images using the data of FIG. 16.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

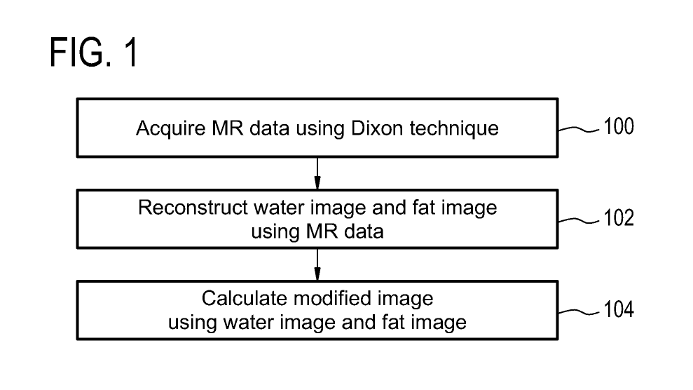

FIG. 1 shows a flowchart which illustrates a method. First in step 100 magnetic resonance data is acquired using a Dixon Pulse Sequence to control a magnetic resonance imaging system. Next in step 102 a water image and a fat image is reconstructed from the acquired magnetic resonance data. The water image comprises a first set of complex valued voxels and the fat image comprises a second set of complex valued voxels. Finally in step 104 a modified image is calculated. The modified image comprises a first set of real valued voxels. The set of real valued voxels is calculated by taking the nth root of the weighted sum of the modulus of the first set of complex valued voxels raised to the power n and the modulus of the second set of complex valued voxels raised to the power n.

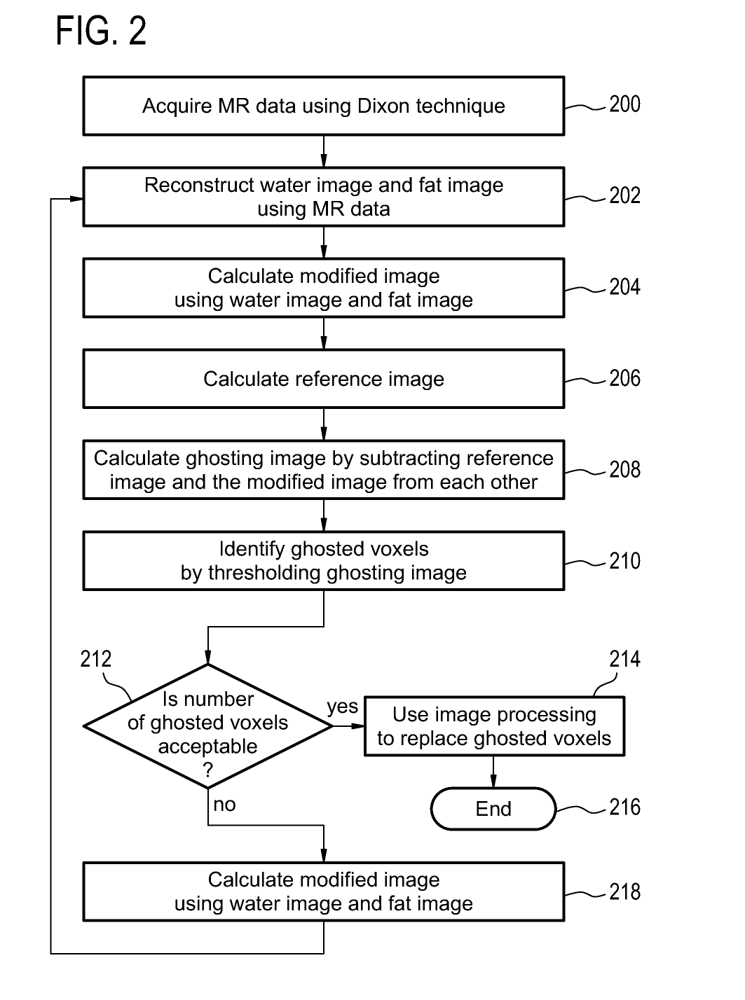

FIG. 2 shows a flowchart which illustrates an alternative method. First in step 200 magnetic resonance data is acquired using a Dixon Pulse Sequence to control a magnetic resonance imaging system. Next in step 202 a water image and a fat image is reconstructed from the acquired magnetic resonance data. The water image comprises a first set of complex valued voxels. The fat image comprises a second set of complex valued voxels. Next in step 204 a modified image is calculated. The modified image comprises a first set of real valued voxels. The set of real valued voxels is calculated by taking the nth root of the weighted sum of the modulus of the first set of complex valued voxels raised to the power n and the modulus of the second set of complex valued voxels raised to the power n. Next in step 206 a reference image is calculated. The reference image is one of a Dixon in-phase image or a Dixon out-of-phase image constructed from the water image and the fat image. The modified image is either linked to an in-phase image or is equivalent to an out-of-phase image. If the weighting is such that both the modulus of the first set of complex valued voxels raised to the power n and the modulus of the second set of complex valued voxels raised to the power n are both of the same sign or both positive or negative in the sum then it is equivalent to an in-phase image. If these two terms have a different sign whereas one is a negative and one is a positive then they are equivalent to a Dixon out-of-phase image. The reference image is constructed such that it is the same as the type of image as the modified image.

Next in step 208 a ghosting image is calculated by subtracting the reference image from the modified image from each other. That is one of the two is subtracted from the other. In some cases the modulus of each of the voxels of the image is taken before the ghosting image is calculated. Next in step 210 a set of ghosted voxels is identified by thresholding the ghosting image. This for instance may be identified by thresholding the magnitude if it is a complex image or simply taking the threshold if the ghosting image is real valued voxels. Water-fat transition areas can be excluded in the ghosting image of real valued voxels. Next in step 212 which is a decision box it is determined if the ghosting is below a predetermined threshold. If this is true then step 214 is performed. In step 214 image processing may be performed to reduce the ghosting in the image. This for instance may include replacing each of the ghosted voxels in the corrected image by averaging voxels at a predetermined distance around each of the ghosted voxels, replacing each of the set of ghosted voxels in the corrected image by identifying the regions of ghosted voxels and averaging voxels bordering the regions of the ghosted voxels, multiplying each of the set of ghosted voxels in the corrected image by a predetermined corrected factor, or a combination thereof. After the image processing 214 is applied the method ends in step 216. If there is too much ghosting still in the image in box 212 then the method proceeds to step 218.

In step 218 k-space lines are modified in the magnetic resonance data. The method then returns to step 202. If the identified ghosted voxels in box 210 does not reduce motion ghosts effectively, k-space lines may not be removed or modified and other k-space lines shall be identified and this is repeated iteratively until the amount of ghosting is reduced, the signal to noise ratio in the Dixon images is not below a specified criteria and the number of iterations has not exceeded a specified performance threshold. In some other alternative examples step 212 is not performed and step 210 proceeds directly to step 214. That is to say that in some examples there is no k-space modification. On the same note, in some examples image processing of the image in step 214 is not performed and the method proceeds directly from step 212 to step 216 if the ghosting or number of ghosted pixels is below a certain threshold.

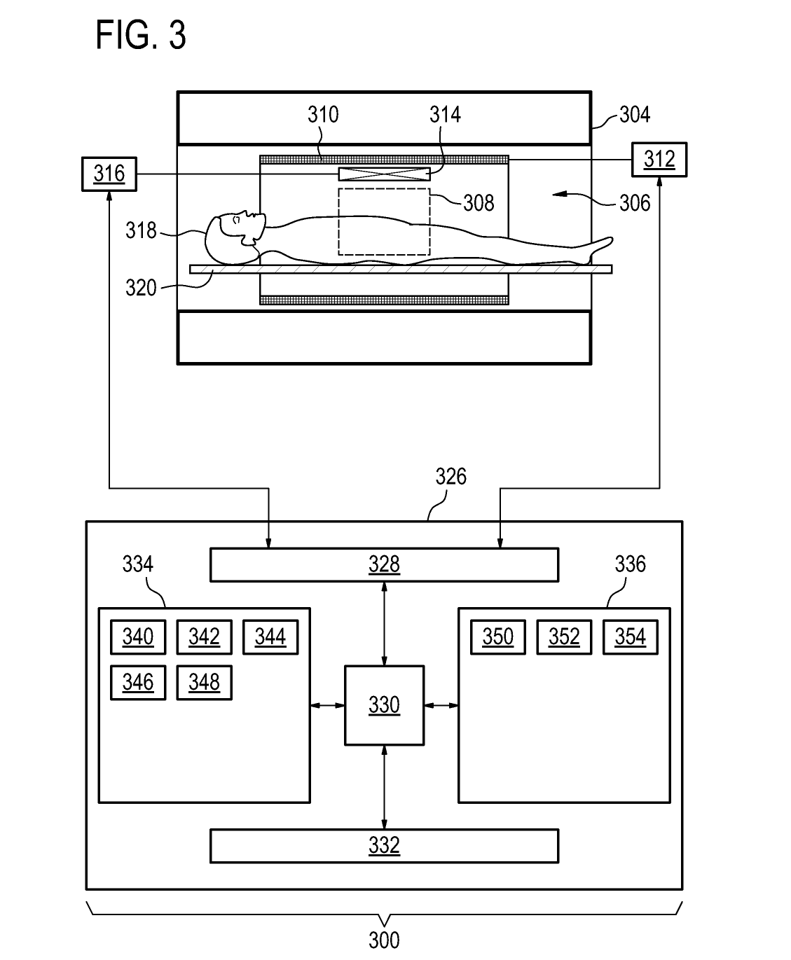

FIG. 3 illustrates an example of a magnetic resonance imaging system 300 according to an embodiment of the invention. The magnetic resonance imaging system 300 comprises a magnet 304. The magnet 304 is a superconducting cylindrical type magnet 304 with a bore 306 through it. The use of different types of magnets is also possible for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject: the arrangement of the two sections area similar to that of a Helmholtz coil. Open magnets are popular, because the subject is less confined. Inside the cryostat of the cylindrical magnet there is a collection of superconducting coils. Within the bore 306 of the cylindrical magnet 304 there is an imaging zone 208 where the magnetic field is strong and uniform enough to perform magnetic resonance imaging.

Within the bore 306 of the magnet there is also a set of magnetic field gradient coils 310 which is used for acquisition of magnetic resonance data to spatially encode magnetic spins within the imaging zone 308 of the magnet 304. The magnetic field gradient coils 310 connected to a magnetic field gradient coil power supply 312. The magnetic field gradient coils 310 are intended to be representative. Typically magnetic field gradient coils 310 contain three separate sets of coils for spatially encoding in three orthogonal spatial directions. A magnetic field gradient power supply supplies current to the magnetic field gradient coils. The current supplied to the magnetic field gradient coils 310 is controlled as a function of time and may be ramped or pulsed.

Adjacent to the imaging zone 308 is a radio-frequency coil 314 for manipulating the orientations of magnetic spins within the imaging zone 308 and for receiving radio transmissions from spins also within the imaging zone 308. The radio frequency antenna may contain multiple coil elements. The radio frequency antenna may also be referred to as a channel or antenna. The radio-frequency coil 314 is connected to a radio frequency transceiver 316. The radio-frequency coil 314 and radio frequency transceiver 316 may be replaced by separate transmit and receive coils and a separate transmitter and receiver. It is understood that the radio-frequency coil 314 and the radio frequency transceiver 316 are representative. The radio-frequency coil 314 is intended to also represent a dedicated transmit antenna and a dedicated receive antenna. Likewise the transceiver 316 may also represent a separate transmitter and receivers. The radio-frequency coil 314 may also have multiple receive/transmit elements and the radio frequency transceiver 316 may have multiple receive/transmit channels.

The magnetic field gradient coil power supply 312 and the transceiver 316 are connected to a hardware interface 328 of computer system 326. The computer system 326 further comprises a processor 330. The processor 330 is connected to the hardware interface 328, a user interface 332, computer storage 334, and computer memory 336.

The computer storage 334 is shown as containing a pulse sequence 340 for performing a Dixon method to acquire magnetic resonance data. The computer storage 334 is further shown as containing magnetic resonance data 342 that was acquired using the pulse sequence 340. The computer storage is further shown as containing a fat image 344 which is reconstructed from the magnetic resonance data 342. The computer storage is further shown as containing a water image 346 that was reconstructed from the magnetic resonance data 342. The fat image 344 and the water image 346 are reconstructed according to a Dixon method. The computer storage 334 is further shown as containing a modified image 348 that was calculated using the fat image 344 and the water image 346. The modified image comprises a first set of real valued voxels and the real set of voxels was calculated by taking the nth root of the weighted sum of the fat image 344 raised to the power n and the modulus of the second set of complex valued voxels which make up the other image 346 raised to the power N. The mathematical operations are performed on each voxel individually.

The computer memory 336 is shown as containing a control module 350. The control module contains computer executable code which enables the processor 330 to control the operation and function of the magnetic resonance imaging system 300. For instance the pulse sequence 340 may enable the control module 350 to acquire the magnetic resonance data 342. The computer memory 336 is further shown as containing an image reconstruction module 352. The image reconstruction module 352 contains computer executable code which enables the processor 330 to reconstruct the fat image 344 and the water image 346. The computer storage 336 contains an image processing module 354 which enables the processor 330 to perform image processing steps. The processor 330 used the image processing module 354 to provide instructions which enabled it to produce the modified image 348 from the fat image 344 and the water image 346.

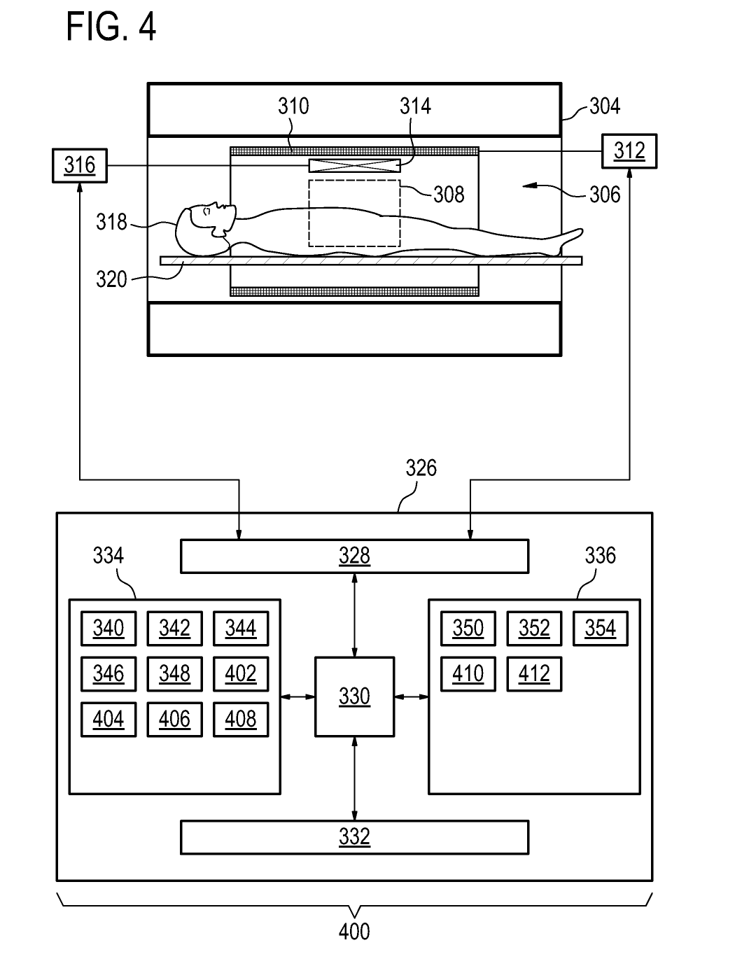

FIG. 4 illustrates a magnetic resonance imaging system 400 similar to that shown in FIG. 3. The computer storage 334 is shown as additionally containing a reference image 402. The reference image is a normal Dixon in-phase image or out-of-phase image constructed by either adding or subtracting the water image and the fat image. The computer storage 334 is shown as further containing a ghosting image 404. The ghosting image was constructed by subtracting one of the reference image and the modified image from each other. The computer storage is further shown as containing a set of ghosted voxels 406 which have been identified in the ghosting image 404 by a thresholding bit. The computer storage 334 is further shown as containing modified magnetic resonance data. The modified magnetic resonance data has had its k-space modified. The modified magnetic resonance data 408 may then be used to recalculate all of the various images present in the computer storage 334.

The computer memory 336 is shown as additionally containing a k-space modification module 410. The k-space modification module 410 contains computer-executable code which enables the processor 330 to remove or calculate particular lines of k-space which may have been corrupted due to motion of the subject 318. For instance the radio-frequency antenna 314 may in fact by a multi-element antenna and there may be multiple elements which use the parallel imaging technique to acquire the magnetic resonance data. The k-space modification module 410 may for instance be used to determine weighting factors between the various antenna elements of the radio-frequency antenna 314. The computer storage 336 is shown as also optionally containing an image correction module 412 which may use one of a variety of image processing techniques to remove or correct ghosting from the reference image 402 or the modified image 348.

The correction module 412 may for instance contain code which enables the processor to: replace each of the ghosted voxels in the corrected image by averaging voxels a predetermined distance around each of the ghosted voxels, replace each of the set of ghosted voxels in the corrected image by identifying the regions of ghosted voxels and averaging voxels bordering the regions of the ghosted voxels, multiplying each of the set of ghosted voxels in the corrected image by a predetermined correction factor, and combinations thereof.

Dixon methods are attractive for water fat separation and B0 field inhomogeneity correction. Especially the multi-acquisition TSE variants typically suffer from motion artifacts due to increased scan times and interleaved acquisition. One of the nice characteristics of Dixon is that motion artifacts are typically encoded either in the fat or water image dependent on their spectral source. Hence in case of fat movement the fat ghost typically is encoded to the fat image, while water movement is encoded to the water image.

Examples may use the different appearance of motion in water and fat Dixon images but also source images to extract motion free water, fat and IP, OP images.

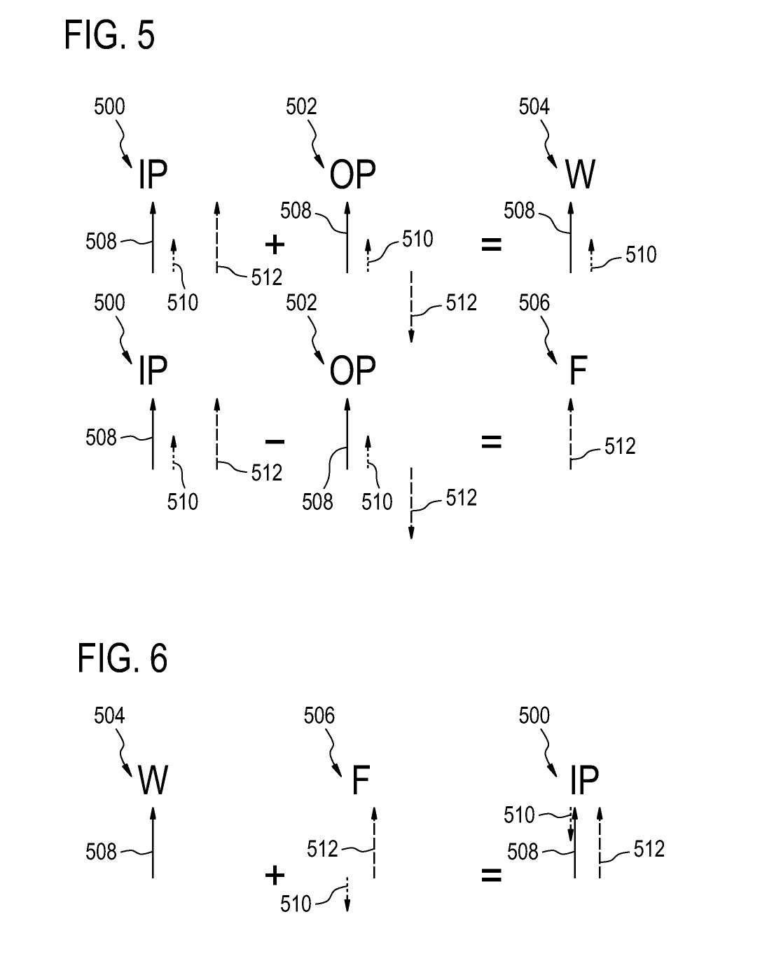

FIG. 5 shows a simple schematic diagram which illustrates the components of various images. The in-phase images are abbreviated IP and labeled 500. Out-of-phase images are labeled 502 and abbreviated OP. The water image is abbreviated W and labeled 504 and the fat image is abbreviated F and labeled 506. The in-phase image 500 comprises a signal with the water, noise, and fat 512. In the first row it can be seen that adding the in-phase and outer-phase images there is signal in the water image 504 which has the water signal 508 and the noise signal 510 due to the ghosting. In the second row the in-phase 500 and the outer-phase images 502 are subtracted from each other. This results in a fat image 506 which only has the fat signal 512.

In Dixon, in-phase images are typically calculated from the complex water and fat images by complex addition of the water and fat signals: IP=|W+F|. Where IP refers to an in-phase Dixon image, W refers to a Dixon water image, and F refers to a Dixon fat or lipid image. Motion ghosts are typically encoded in the water or fat image dependent on the spectral source as shown for the simple in-phase out-phase Dixon example below (W=IP+OP, F=IP−OP). Here water motion leads to a motion ghost or noise 510 in the water image and not in the fat image.

It is possible to use the different appearance of motion in water and fat Dixon images but also source images to extract motion free water, fat and IP, OP images. Note that the source images acquired at different echo times typically has a different flow appearance due to their first and higher order moment differences.

This extraction for example can be done by k-space consistency analysis and comparisons (e.g. COCOA) of the water, fat and source data sets. In case of fat ghosts for example a selective de-ghosting of the fat images could be achieved based on the k-space redundancy.

This extraction for example be also done by simply modulus addition (see description below).
IP/OP images: In case a fat ghost is present this ghosting signal typically is complex. When adding this complex signal to water the water signal can be reduced by the motion ghost leading to a visible reduction of the water signal. In modulus addition (IP=|W|+|F|), the signal always is increased. This signal addition however is less visible to the eye as shown by some of the examples below. Also the motion ghost range is reduced by a factor of 2.

In FIG. 6 the water image 504 only has a water signal 508 and this is added to a fat signal 506 which has motion induced signal ghosts from fat 510 and the fat signal 512. The resulting in-phase image 500 has the fat signal plus the water signal 508. However, the effect of the signal ghost from fat 510 reduces the magnitude of the water signal 508.
W/F images: In case of the water image weigh the fat image with a low weighing factor (for example wf=0.1) and modulus add it to the water image. W=|W|+wf*|F|. This way flow ghosts from vessels are visually improved as shown below (see red arrow). Vice versa in case of fat images weigh the water image with a low weighing factor and modulus add it to the fat image. F=wf*|W|+|F|.

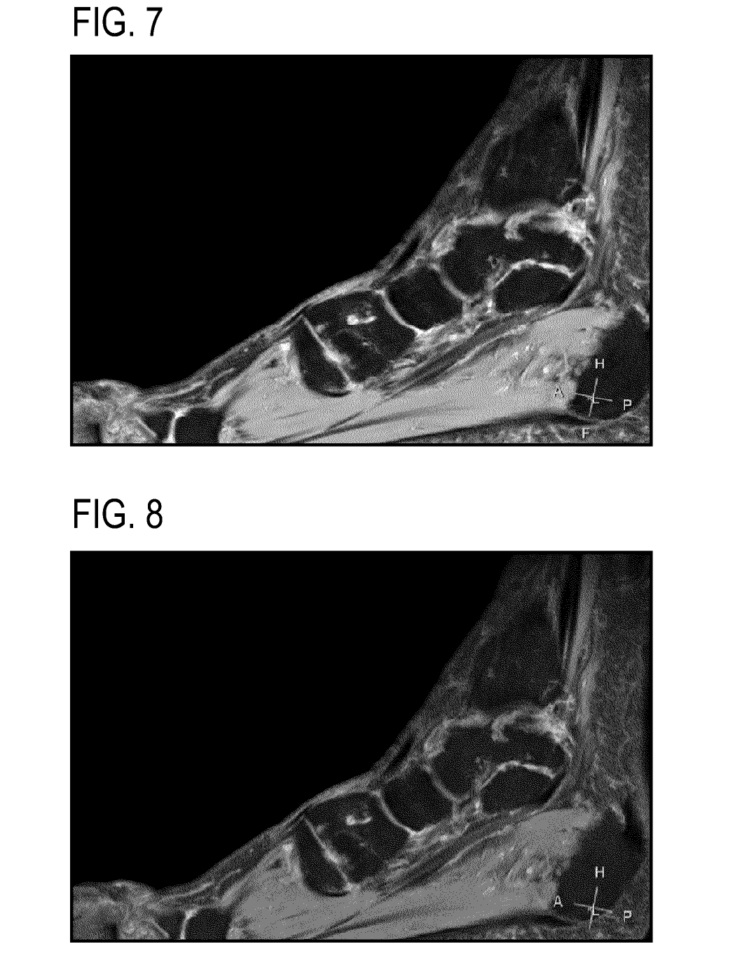

FIG. 7 shows a magnetic resonance water image of a foot that was acquired using a Dixon method.

FIG. 8 shows the same water image reconstructed using the water and fat image with the water image weighted by a factor of 1 and the fat image weighted by a factor of 0.1. It can be seen that there is a reduced amount of ghosting in the FIG. 8.

This extraction for example can be further done by subtraction of the complex and modulus derived IP (OP) images, hard ghosting lines from motion are visible. With this simple analysis but also a more complex analysis on the amplitude and phase differences, ghosts above a specified noise threshold could be detected and a subsequent analysis and reduction of the artifact could be done. Note some precaution needs to be taken to exclude water fat transition areas.

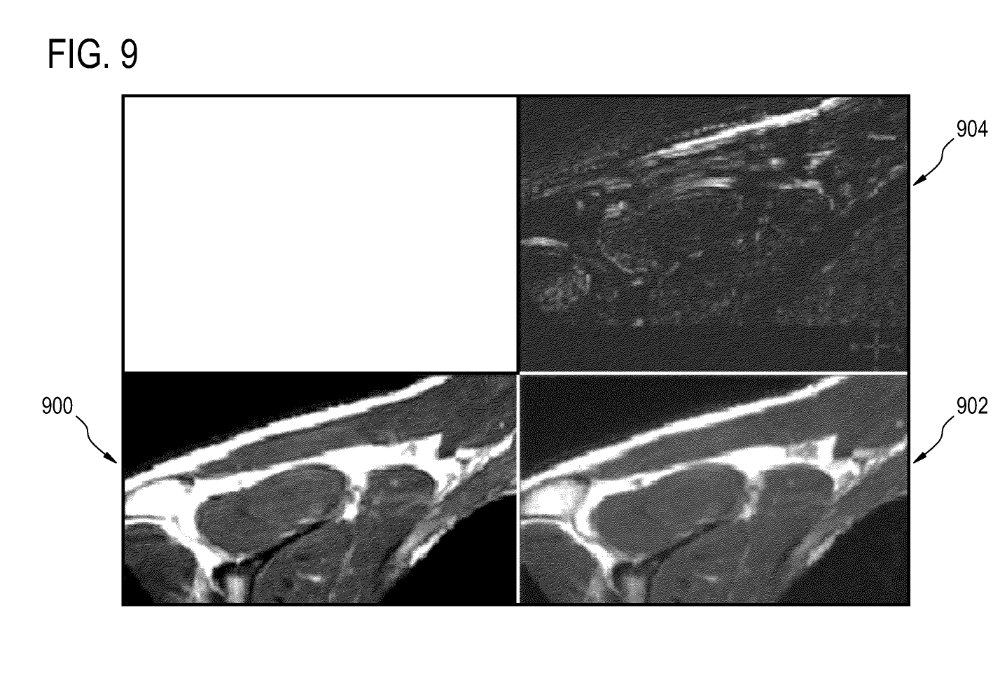

FIG. 9 illustrates the calculation of a ghosting image. Image 900 is a magnetic resonance image constructed in a manner according to a normal Dixon in-phase image. The water and fat images were added using complex addition. FIG. 900 is referred to in the claims as a reference image. FIG. 9 also illustrates FIG. 902. 902 is a modified image that was constructed using modulus addition between the water and fat image. The image 902 is referred to herein as a modified image. The image 904 is the result of subtracting image 902 from image 900. The image 904 is referred to herein as a ghosting image. The bright areas in the image 904 indicate artifacts due to motion of the subject.

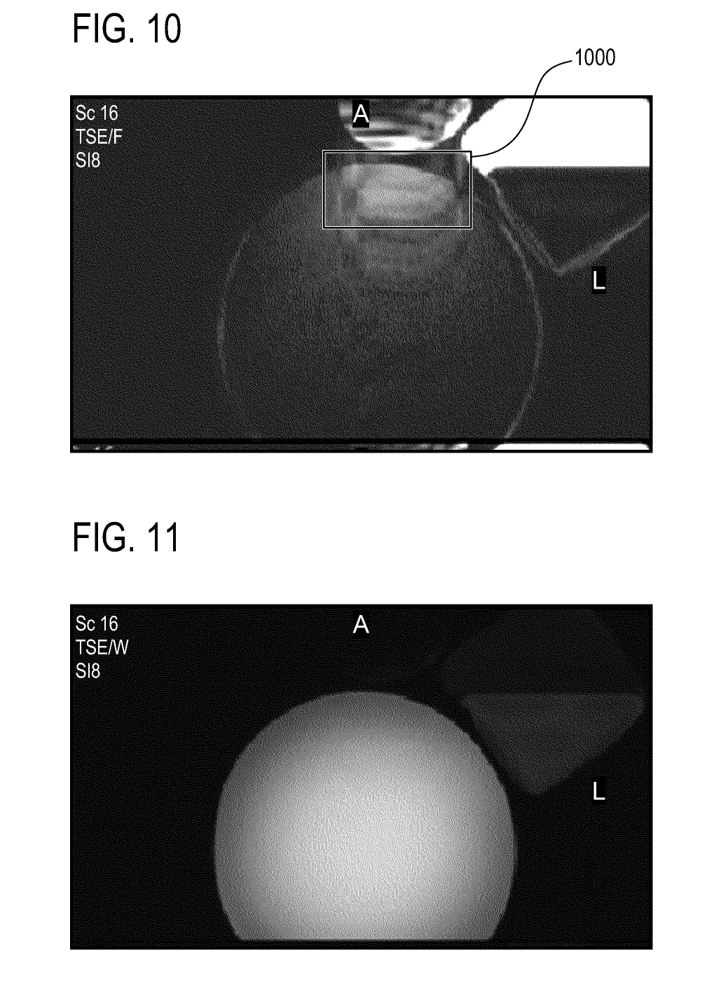

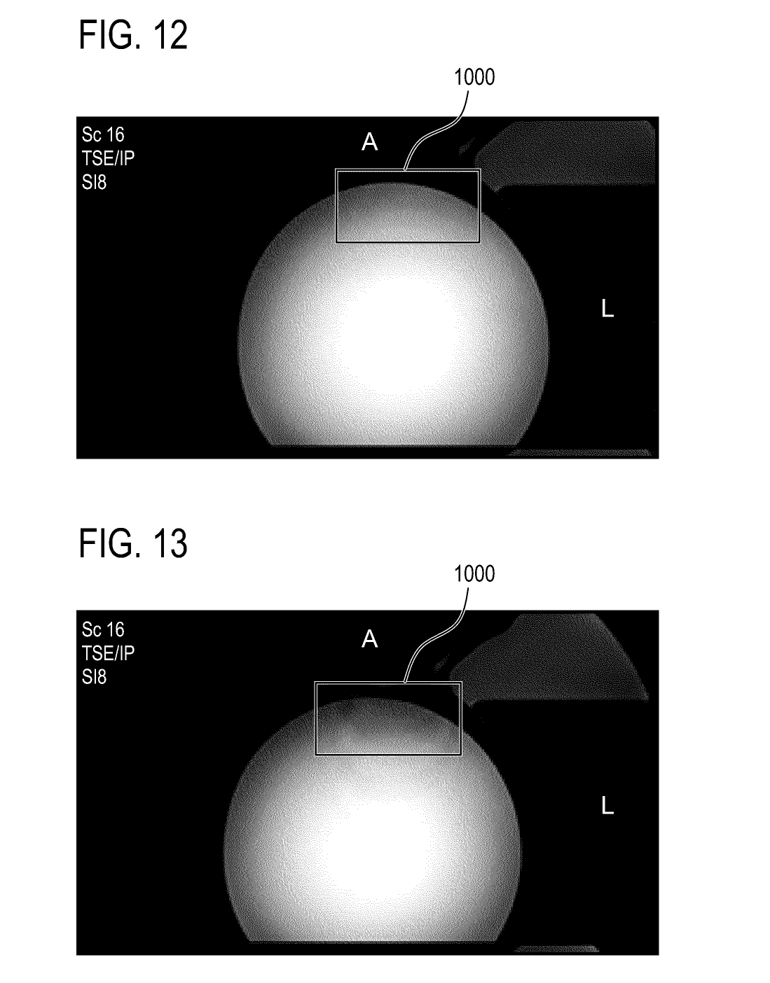

FIGS. 10-13 show a cross-sectional view of a setup of water and fat phantoms with a small fat phantom which has moved during a Dixon magnetic resonance imaging scan. During this the scan was paused and the fat phantom was shifted. Motion is shown predominantly in the fat image. The water image only shows mild effects. FIG. 10 shows the fat image. The box labeled 1000 shows a region in the water phantom which was heavily affected by the movement of the fat phantom showing in ghosting. FIG. 11 shows the water image. FIG. 12 is an image which was reconstructed using modulus addition of FIGS. 10 and 11. In the box 1000 in FIG. 12 it can be seen that there are very few artifacts visible. FIG. 13 shows the sum of FIGS. 10 and 11 using complex addition. Inside a box 1000 in FIG. 13 there is a larger number of artifacts visible.

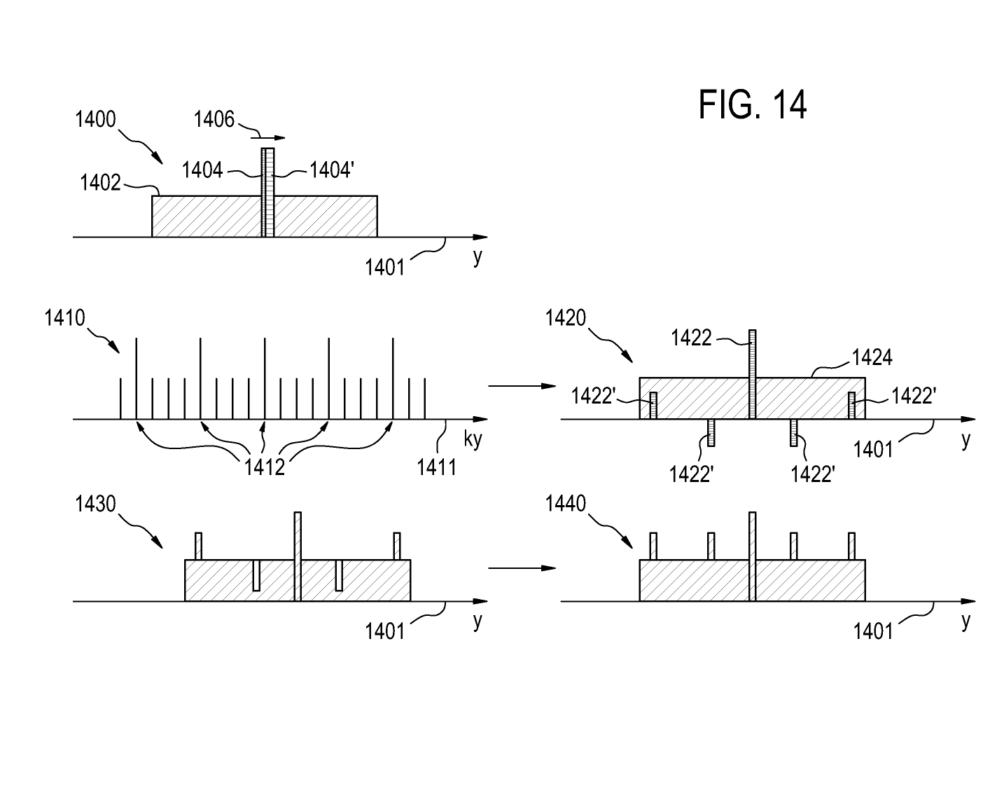

FIG. 14 shows several diagrams which illustrate the benefit of using in-phase addition of the water and fat images. Diagram 1400 shows a y-axis with some water 1402 and some fat 1404. During the acquisition of the magnetic resonance data the fat 1404 is moved with a motion-induced phase shift. (Note to self: insert formula here). The fat in its furthest extent of travel is shown in position 1404. The vector 1406 represents this movement. Next graph 1410 shows a representation of the magnetic resonance data which has been acquired. It is plotted along in k-space 1411. The k-space lines marked 1412 are corrupted k-space lines. They are due to the corrupted TSE shot. Diagram 1420 shows the fat images and water images superimposed upon each other. The block labeled 1424 represents the water image. The blocks labeled 1422 and 1422′ represent the fat image. In the fat image the fat is represented by 1422 and the ghosts of the fat movement are labeled 1422′. 1430 shows the complex sum of the water 1424 and the fat images 1422, 1422′. Graph 1440 shows the result of the modulus addition of the water image 1424 and the fat image 1422, 1422′. In comparing 1430 and 1440 it can be seen that the dynamic ghost range has been reduced by a factor of 2. FIG. 14 illustrates the benefit of not necessarily adding the complex water and fat images.

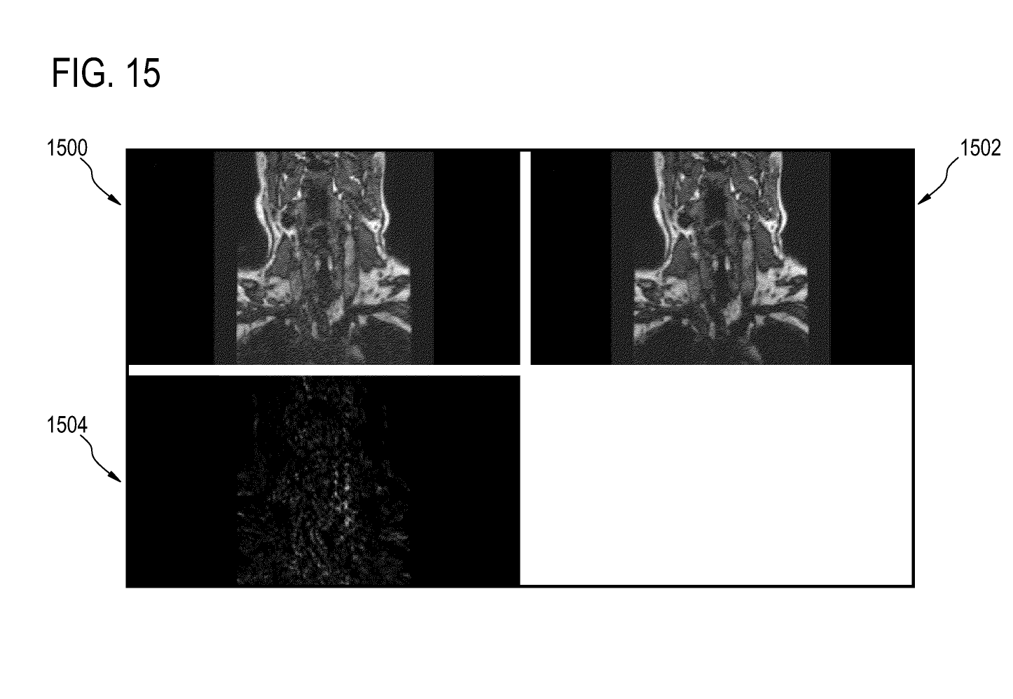

FIG. 15 illustrates the calculation of a ghosting image 1504. Image 1500 is a normal Dixon in-phase image that was calculated by adding the complex water and complex fat images to each other. Image 1502 shows a modulus addition in-phase image that was calculated by adding the modulus of the water image to the modulus of the fat image. The image 1504 shows the difference obtained by subtracting image 1502 from image 1500. The bright areas visible in 1504 are areas which have been affected by ghosting artifacts due to motion of the subject. Image 1504 illustrates how it is easy to obtain a quantitative estimate of the amount of ghosting using the comparison of the images 1500 and 1502.

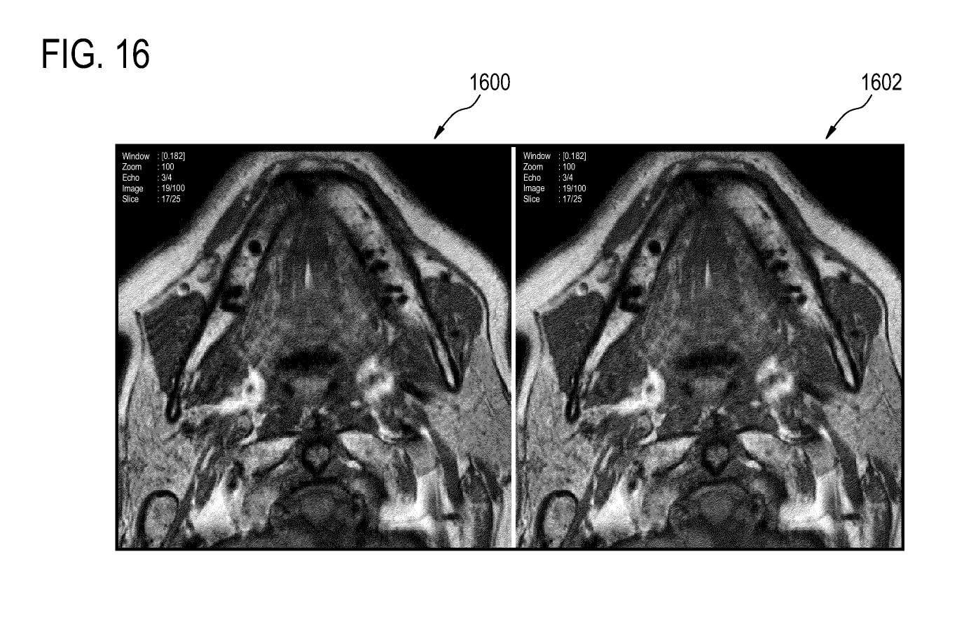

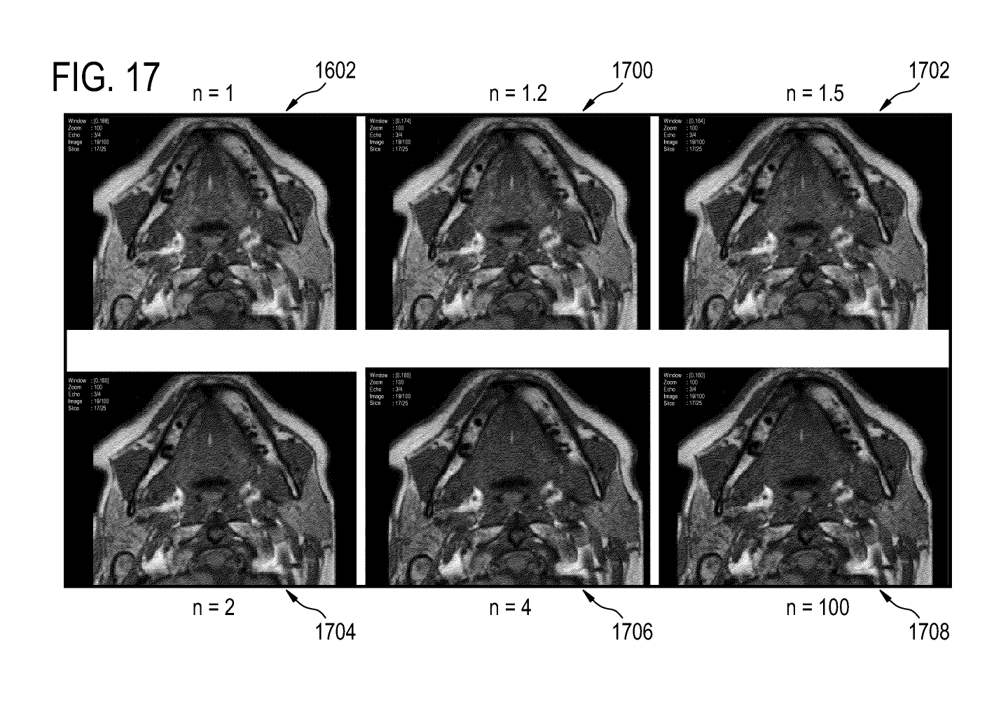

FIGS. 16-21 compare the modulus addition raised to different powers. (Note to self: insert formula and short description here).

FIG. 16 shows two images. Image 1600 shows a transverse cross-sectional view of the lower mandible and skull. Image 1600 has all the images in FIGS. 16-21 were acquired using a Dixon technique. Image 1600 shows the complex addition of the water and fat images. Image 1602 shows the simple modulus addition of the water and fat images.

FIG. 17 shows the resulting image for the modulus addition of different powers of n. Image 1602 shows the modulus addition of the water and fat image when the power n is equal to 1. Image 1700 shows the same modulus addition except the power is raised to the power of 1.2. Image 1702 shows the modulus addition of the fat and water images when n is equal to 1.5. Image 1704 shows the modulus addition when n is equal to 2. Image 1706 shows the modulus addition when n is equal to 4. And finally image 1708 shows the modulus addition when N is equal to 100.

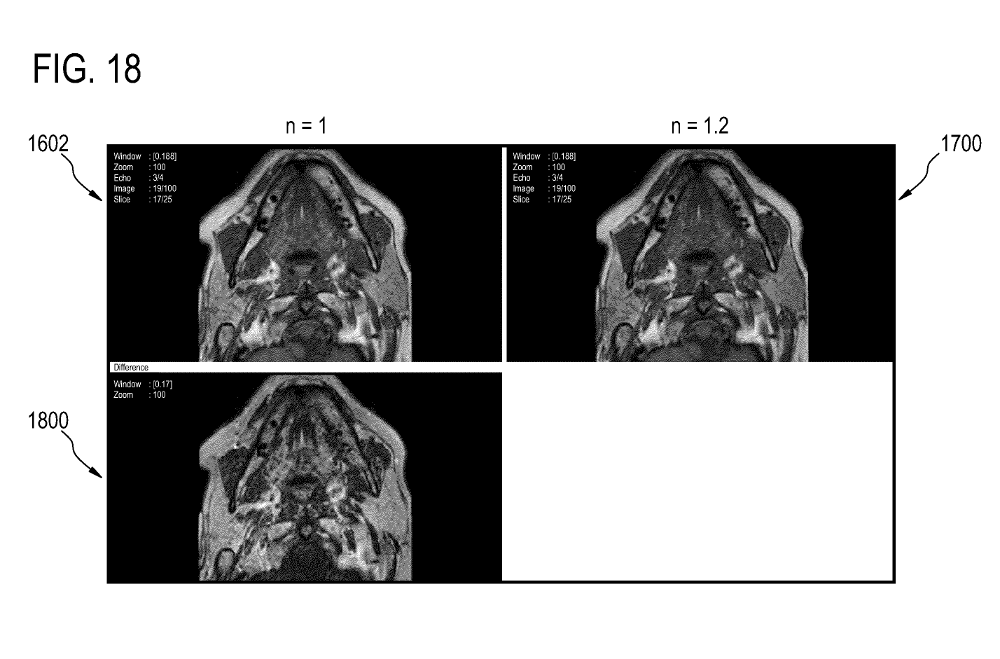

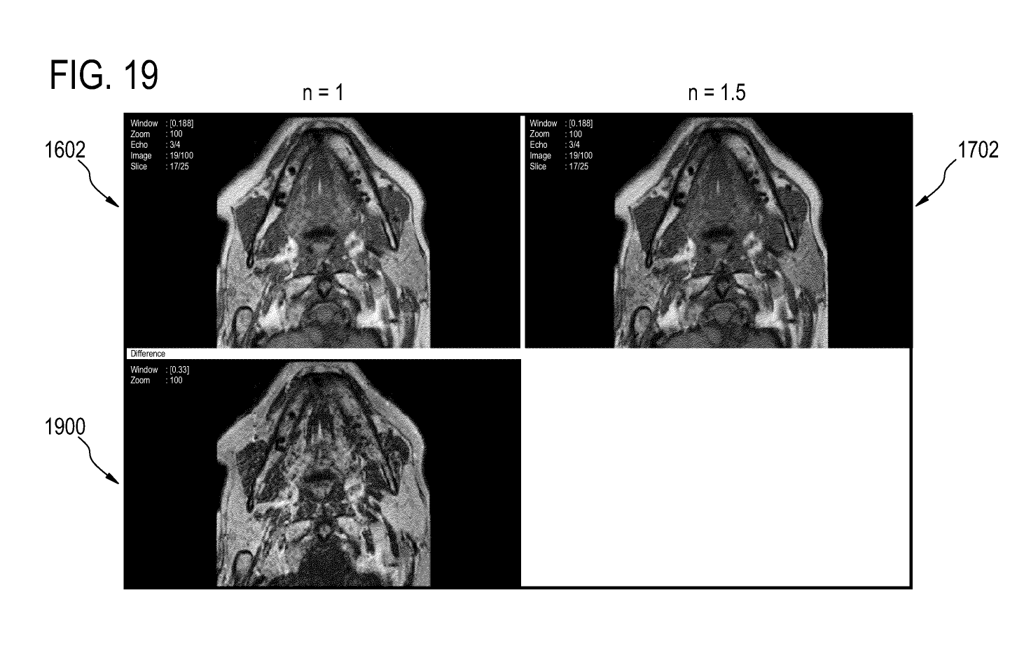

FIG. 18 shows images 1602 and 1700 again. Image 1800 is the difference between images 1602 and image 1700.

FIG. 19 shows images 1602 and image 1702 again. Image 1900 also shown in FIG. 19, shows differences between image 1602 and image 1702.

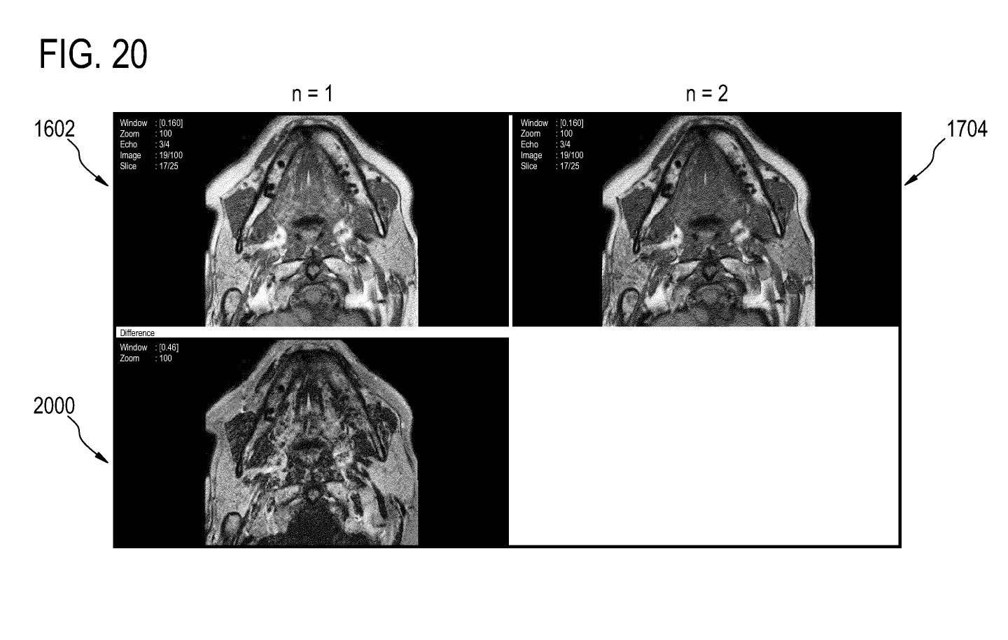

FIG. 20 shows image 1602 again and image 1704. Image 2000 also shown in FIG. 20 shows the difference between image 1602 and image 1704.

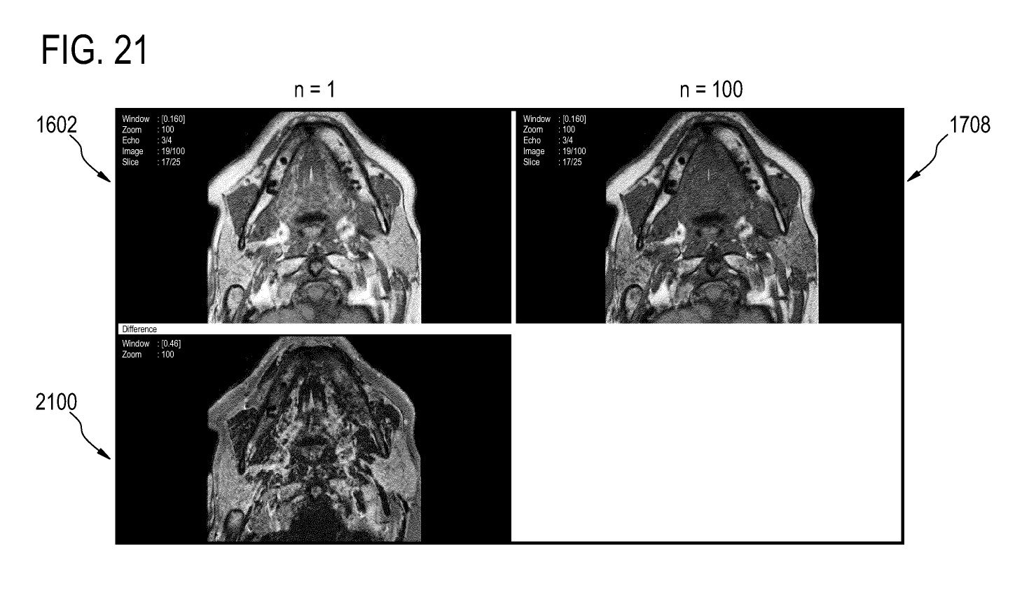

FIG. 21 shows images 1602 and image 1708 again. The image 2100 is also shown in FIG. 21 and shows the difference between 1602 and image 1708. The difference between 1602 and image 1706 is visible on a computer or emissive screen however; it is not distinguishable from image 2100 when printed on common paper. For this reason the difference between image 1602 and 1706 is not included.

Images 1800, 1900, 2000, and 2100 may be compared to illustrate how using higher powers of n may affect the construction of a modified image. As higher powers of n are approached there is a certain thresholding effect towards a number being multiplied by itself repeatedly.

Dixon methods permit a more robust fat suppression in the presence of main field inhomogeneity than selective saturation or excitation methods. They involve an encoding of the chemical shift by repeated measurements at different echo times. While these echo times were originally fixed to in- and opposed-phase echo times, their choice is usually more flexible today. “Opposed-phase echo” times may also be referred to as out-of phase. However, in- and opposed-phase images are often still requested in addition to water and fat images. Since they are no longer directly acquired, they have to be synthesized, for instance by adding and subtracting the water and fat images.

The thus obtained in-phase image and opposed-phase image (or out-of-phase image) show the constructive and destructive superposition of water and fat signals at different echo times, but they do not reflect any decay due to transverse relaxation. Certain diseases, such as hemochromatosis, i.e. the accumulation of iron in the liver, manifest themselves in acquired in- and opposed-phase images by weaker signals at later echo times. If the in-phase echoes are sampled after the opposed-phase echoes, weaker signals in the former are only explicable by relaxation, providing an unambiguous indication for the presence of iron. On the basis of the currently available synthesized in- and opposed-phase images, such a diagnosis is impossible.

It is possible to include relaxation in the recombination of water and fat images. Depending on the number of echo times at which the repeated measurements are performed, it suggests to detect the presence or to estimate the extent of transverse relaxation and to adapt the signal amplitudes in the synthesized in- and opposed-phase images accordingly.

Assuming a multi-peak spectral model of fat, the composite complex signal in image space S, sampled at echo times tₙ, is given by

Sₙ=(W+cₙF)e^{iφ}^{ₙ},

where W and F denote the water and fat signals in image space, and φ and e^{iφ} denote a phase error and the corresponding phasor. The complex factor c is defined by:

cₙ=Σₘwₘe^{iθ}^{_{n,m}},

with w being weights that add up to one and θ being de-phasing angles given by

θ_{n,m}=2πΔfₘtₙ,

where Δf is the offset in resonance frequency of a peak of the fat spectrum with respect to water.

Given W and F, the synthesis of in- and opposed-phase signals S_{IP} and S_{OP} involves either a complex addition and subtraction

|S_{IP}|=|W+F|,

|S_{OP}|=|W−F|,

or a magnitude addition and subtraction

|S_{IP}|=|W|+|F|,

|S_{OP}|=∥W|−|F∥,

of W and F. Optionally, the complex factor c for the respective in- and opposed-phase echo times t_{IP} and t_{OP} may be included in these equations.

The use of a multi-peak spectral model of fat offers the fundamental advantage of providing true in- and opposed-phase signals, i.e. signals in which the contributions from water and from the individual peaks of the fat spectrum are exactly in- and opposed-phase. Such signals can usually not be acquired efficiently, with the exception of true in-phase signals with spin-echo sequences.

Including transverse relaxation leads to

Sₙ=(W+cₙF)e^{-r}^{ₙ}^{+iφ}^{ₙ},

with r describing the common decay of water and fat signals.

If the repeated measurements are performed at at least three equispaced echo times, and if r and φ are assumed to evolve linearly over echo time, the available amount of data is sufficient to estimate the increments in r and φ or e^{1φ}. The calculation of S_{IP} and S_{OP} may then be extended to

|S_{IP}|=|W+F|e^{-r}^{_{IP}},

|S_{OP}|=|W−F|e^{-r}^{_{OP}},

and

|S_{IP}|=(|W|+|F|)e^{-r}^{_{IP}},

|S_{OP}|=∥W|−|F∥e⁻^{_{OP}},

where r_{IP} and r_{OP} are derived from Δr, the increment in r given by R Δt, the product of a relaxation rate R and the echo spacing Δt, according to

r_{IP}=Δrt_{IP}/Δt,

r_{OP}=Δrt_{OP}/Δt.

A map of the implicitly obtained relaxation rate R may be displayed in addition to the separated water and fat images and the synthesized in- and opposed-phase images.

Provided that the available amount of data is sufficient, more complex models of relaxation, for instance to consider differences in relaxation rates between water and fat or between the individual peaks of the fat spectrum, may be employed.

If the repeated measurements are performed at two echo times only, the available amount of data is in general insufficient to determine the extent of transverse relaxation. However, if the water and fat signals are more in-phase at the second echo time, a detection of decay is possible, since weaker composite signals at the second echo time are only explicable by relaxation. This may be exploited to mark corresponding voxels in the in- or opposed-phase images, for instance.

Moreover, making the assumption that only water or fat is present in single voxels, even an estimation of Δr is feasible, simply by attributing the observed loss in signal amplitude solely to decay. A violation of this assumption leads to a benign underestimation of Δr. The thus obtained values for Δr may be employed to adapt the signal amplitudes in the synthesized in- and opposed-phase images, as for the case of more than two echo times.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

300 magnetic resonance imaging system
304 magnet
306 bore of magnet
308 imaging zone
310 magnetic field gradient coils
312 magnetic field gradient coil power supply
314 radio-frequency coil
316 transceiver
318 subject
320 subject support
326 computer system
328 hardware interface
330 processor
332 user interface
336 computer storage
338 computer memory
340 pulse sequence
342 magnetic resonance data
344 fat image
346 water image
348 modified image
350 control module
352 image reconstruction module
354 image processing module
400 magnetic resonance imaging system
402 reference image
404 ghosting image
406 set of ghosted voxels
408 modified magnetic resonance data
410 k-space modification module
412 image correction module
500 in-phase image
502 out-of-phase image
504 water image
506 fat image
508 water signal
510 noise signal
512 fat signal
900 reference image
902 modified image
904 ghosting image
1000 region of interest
1400 subject in xy space
1401 y axis
1402 water
1204 fat
1404′ fat after movement
1406 movement vector
1410 magnetic resonance data
1412 corrupted k-space lines
1420 fat Dixon image and water image superimposed
1422 fat image
1422′ ghost of fat image
1424 water image
1430 complex addition in-phase image
1440 modulus addition in-phase image
1500 complex addition in-phase image (reference image)
1502 modulus addition in-phase image (modified image)
1504 difference between 1500 and 1502 (ghosting image)
1600 complex addition in-phase image
1602 modulus addition in-phase image (n=1)
1700 modulus addition in-phase image (n=1.2)
1702 modulus addition in-phase image (n=1.5)
1704 modulus addition in-phase image (n=2)
1706 modulus addition in-phase image (n=4)
1708 modulus addition in-phase image (n=100)
1800 difference image between 1602 and 1700
1900 difference image between 1602 and 1702
2000 difference image between 1602 and 1704
2100 difference image between 1602 and 1708

1. A magnetic resonance imaging system for acquiring magnetic resonance data from an imaging zone, wherein the magnetic resonance imaging system comprises:
a processor for controlling acquisition of magnetic resonance data;
a memory containing machine executable instructions for execution by the processor and a specification of a Dixon pulse sequence for performing a Dixon magnetic resonance imaging method, wherein execution of the instructions cause the processor to:
acquire the magnetic resonance data using the Dixon pulse sequence;
reconstruct a water image and a fat image from the acquired magnetic resonance data, wherein the water image comprises a first set of complex valued voxels and the fat image comprises a second set of complex valued voxels; and
calculate a modified image comprising a first set of real valued voxels, wherein the set of real valued voxels is calculated as follows:
for each voxel, its real value is calculated by taking the nth root of the weighted sum of the modulus of the complex value at the corresponding voxel of the first set of complex valued voxels raised to the power n and modulus of the complex value at the corresponding voxel of the second set of complex valued voxels raised to the power n, with n>1.

2. The magnetic resonance imaging system of claim 1, wherein execution of the instructions causes the processor to:
calculate a reference image, wherein the reference image is a Dixon in-phase image or a Dixon out-of-phase image constructed from the water image and the fat image;
calculate a ghosting image by subtracting the reference image and the modified image from each other;
identify a set of ghosted voxels by thresholding the ghosting image; and
calculate a corrected image using the set of ghosted voxels to locate ghosting artifacts due to motion.

3. The magnetic resonance imaging system of claim 2, wherein execution of the instructions further cause the processor to calculate the corrected image at least partially by iteratively modify k-space lines from the magnetic resonance data to minimize the number of ghosted voxels in the set of ghosted voxels after recalculating the water image, the fat image, the modified image, and the reference image.

4. The magnetic resonance imaging system of claim 2, wherein execution of the instructions further causes the processor to calculate the corrected image at least partially by performing any one of the following: replace each of the ghosted voxels in the corrected image by averaging voxels a predetermined distance around each of the ghosted voxels, replace each of the set of ghosted voxels in the corrected image by identifying regions of ghosted voxels and averaging voxels bordering the regions of the ghosted voxels, multiply each of the set of ghosted voxels in the corrected image by a predetermined correction factor, and combinations thereof.

5. The magnetic resonance imaging system of claim 2, wherein the corrected image is any one of the following: a corrected water image, a corrected fat image, a corrected Dixon in-phase image, and/or a corrected Dixon out-of-phase image.

6. The magnetic resonance imaging system of claim 2, wherein execution of the instructions further causes the processor to:
identify a water-fat transition area in the corrected image using the fat image and the water image, and
remove ghosted voxels within the water-fat transition area from the set of ghosted voxels.

7. The magnetic resonance imaging system of claim 1, wherein execution of the instructions further cause the processor to apply a water-fat shift correction to the fat image before calculating the modified image.

8. The magnetic resonance imaging system of claim 1, wherein execution of the instructions further cause the processor to multiply the modulus of the second set of complex valued voxels to the power n by a fat weighting constant before adding the modulus of second set of complex valued voxels to the power n to the first set of complex valued voxels to the power n, wherein the fat weighting constant is preferably between 0.01 and 0.99, and wherein the fat weighting constant is more preferably between 0.05 and 0.15, and wherein n is an integer greater than 1.

9. The magnetic resonance imaging system of claim 1, wherein execution of the instructions further cause the processor to multiply the modulus of first set of complex valued voxels to the power n by a water weighting constant before adding the modulus of the second set of complex valued voxels to the power n to the modulus of the first set of complex valued voxels to the power n, wherein the water weighting constant is preferably between 0.01 and 0.99, wherein the water weighting constant is more preferably between 0.05 and 0.15.

10. The magnetic resonance imaging system of claim 1, wherein the modified image is calculated using a formula algebraically equivalent to Mᵢ=(w_{w}|Wᵢ|ⁿ+w_{f}|Fᵢ|ⁿ)^{1/n}, Mᵢ is the i^{th} voxel of the modified image, wherein Wᵢ is the i^{th} voxel of the water image, wherein Fᵢ is the i^{th} voxel of the fat image, wherein w_{w} is a water weighting constant, and wherein w_{f} is a fat weighting constant.

11. The magnetic resonance imaging system of claim 10, wherein the ratio w_{f}/w_{w} is positive.

12. The magnetic resonance imaging system of claim 10, wherein the ratio w_{f}/w_{w} is negative.

13. (canceled)

14. A method of operating a magnetic resonance imaging system, wherein the magnetic resonance imaging system is operable for acquiring magnetic resonance data from an imaging zone, wherein the method comprises the steps of:
acquiring the magnetic resonance data using a Dixon pulse sequence to control the magnetic resonance imaging system;
reconstructing a water image and a fat image from the acquired magnetic resonance data, wherein the water image comprises a first set of complex valued voxels, wherein the fat image comprises a second set of complex valued voxels; and
calculating a modified image comprising a first set of real valued voxels, wherein the set of real valued voxels is calculated in that
for each voxel, its real value is calculated by taking the n^{th} root of the weighted sum of the modulus of the complex value at the corresponding voxel of the first set of complex valued voxels raised to the power n and modulus of the complex value at the corresponding voxel of the second set of complex valued voxels raised to the power n, with n>1.

15. A computer program product, stored on a non-transitory computer readable medium, comprising machine executable instructions for execution by a processor controlling a magnetic resonance imaging system for acquiring magnetic resonance data from an imaging zone, wherein execution of the instructions cause the processor to:
acquire the magnetic resonance data using a Dixon pulse sequence to control the magnetic resonance imaging system;
reconstruct a water image and a fat image from the acquired magnetic resonance data, wherein the water image comprises a first set of complex valued voxels, wherein the fat image comprises a second set of complex valued voxels; and
calculate a modified image comprising a first set of real valued voxels, wherein the set of real valued voxels is calculated in that
for each voxel, its real value is calculated by taking the nth root of the weighted sum of the modulus of the complex value at the corresponding voxel of the first set of complex valued voxels raised to the power n and modulus of the complex value at the corresponding voxel of the second set of complex valued voxels raised to the power n, with n>1.

16. A magnetic resonance imaging system for acquiring magnetic resonance data from an imaging zone, wherein the magnetic resonance imaging system comprises:
a processor for controlling the magnetic resonance imaging system;
a memory containing machine executable instructions for execution by the processor and a specification of a Dixon pulse sequence for performing a Dixon magnetic resonance imaging method, wherein execution of the instructions cause the processor to:
acquire the magnetic resonance data using the Dixon pulse sequence to control the magnetic resonance imaging system;
reconstruct a water image and a fat image from the acquired magnetic resonance data, wherein the water image comprises a first set of complex valued voxels, wherein the fat image comprises a second set of complex valued voxels; and
calculate a modified image comprising a third set of voxels, wherein the processor is programmed to calculate the value of a function and to calculate the inverse of the function, wherein the third set of voxels is calculated by applying the inverse of the function to the sum of the function applied to the first set of complex valued voxels and the function applied to the second set of complex valued voxels, wherein the function is invertible to calculate the inverse of the function, wherein the function applied to zero has the value of zero, and wherein the second derivative of the function is positive for the first set of complex valued voxels and the second set of complex valued voxels.
